(19) United States
(12) Patent Application Publication
(10) Pub. No.: US 2008/0283752 A1
(43) Pub. Date: Nov. 20, 2008

(54) Electromagnetic Wave Sensor with Terahertz Bandwidth

(76) Inventors: Romain Czarny, Chatillon (FR); Daniel Dolfi, Orsay (FR); Carlo Sirtori, Paris (FR)

Correspondence Address: LOWE HAUPTMAN & BERNER, LLP, 1700 DIAGONAL ROAD, SUITE 300, ALEXANDRIA, VA, 22314, US

(21) Appl. No.: 12/091,526

(22) PCT Filed: Oct. 24, 2006
(86) PCT No.: PCT/EP06/67695

§ 371 Date: Apr. 25, 2008

(30) Foreign Application Priority Data
Oct. 25, 2005 (FR) 0510875

(51) Int. Cl. H01L 27/14; G01T 1/24

(52) U.S. Cl. 250/338.4; 250/370.01

(57) ABSTRACT

The field of the invention is that of the detection of high frequency electromagnetic waves. The invention can be applied to a very wide range of bandwidths, but the preferred field of application is the terahertz frequency domain. The core of the detection device involves a so-called active material with an absorption coefficient in the optical domain that depends on the intensity of the terahertz signal to be detected. By measuring the variations of the absorption coefficient by means of an optical probe, the intensity of the terahertz signal is thus determined. By this means, a frequency translation is performed in a frequency domain where the measurement no longer poses technical problems. It is notably possible to improve the sensitivity of the detector by having antennas suited to the active medium, by using semiconductor or quantum well materials. In this case, it is also possible to produce a matrix or an array of terahertz sensors, thereby enabling either terahertz imaging or terahertz spectroscopy to be carried out.

### CROSS REFERENCE TO RELATED APPLICATIONS

The present Application is based on International Application No. PCT/EP2006/067695, filed on Oct. 24, 2006, which in turn corresponds to French Application No. 0510875, filed on Oct. 25, 2005, and priority is hereby claimed under 35 USC §119 based on these applications. Each of these applications are hereby incorporated by reference in their entirety into the present application.

### BACKGROUND OF THE INVENTION

1. Field of the Invention

The field of the invention is that of the detection of high frequency electromagnetic waves. The invention can be applied to a very wide range of bandwidths, but the preferred field of application is the terahertz frequency domain.

This frequency domain located at the boundary between the far infrared and the millimetric waves presents a number of interesting technical and industrial aspects in as much as the absorption or reflection properties of the material can be substantially different in this range of wavelengths. Of notable mention are the applications in the medical imaging field and the applications for certain control and security systems. These devices are also used for applications in metrology.

2. Description of the Prior Art

The detection of very high frequency electromagnetic waves is, however, relatively difficult to achieve and represents a major obstacle to the development of the terahertz technologies. The current offering of sensors is relatively weak and the sensors are complex. The most commonly used sensors are the bolometers which measure the thermal variation of a supraconducting film induced by the electrical field of the wave to be detected. While the bolometers present very good sensitivities, they must nevertheless operate at very low temperatures of the order of a few Kelvins, so imposing very heavy usage constraints. It is also possible to use so-called Golay cells where the assessment of the incident power is done notably by means of the optical measurement of the change of pressure of a gaseous cell, induced by the incident electromagnetic wave. Although very sensitive, these sensors are extremely fragile and support only low levels of illumination.

The object of the invention is to propose a detection device which is sensitive in this high frequency spectral band and which does not present the above drawbacks. As will be seen, the device can operate at ambient temperature and does not include complex components. Furthermore, by producing a matrix of sensors according to the invention, it then becomes possible to perform either terahertz imaging or terahertz spectroscopy.

The core of the invention involves using a so-called active material with an absorption coefficient in the optical domain that depends on the intensity of the terahertz signal to be detected. By measuring the variations of the absorption coefficient, the intensity of the terahertz signal is thus determined. By this means, a frequency transposition is performed in a frequency domain where the measurement no longer poses technical problems.

Throughout the text of the description and the figures, the following conventions have been adopted:
The external signal to be detected is called electromagnetic signal. It is represented by chevrons in the various figures;
The signal internal to the sensor is called optical signal. It is represented by surfaces or arrows with a fill pattern that is a grid of dots in the various figures;
The medium with absorption that varies with the intensity of said electromagnetic signal is called active medium;
The set of optical, opto-mechanical and opto-electronic components used for generating, formatting and detecting the optical signal is called optical probe;
The sensor internal to the optical probe, intended to receive the optical signal, is called photodetector.

### SUMMARY OF THE INVENTION

More specifically, the subject of the invention is a sensor of an electromagnetic signal sent in a first bandwidth, characterized in that it mainly comprises:
An active medium lit by said electromagnetic signal, absorbent in a second electromagnetic bandwidth, the absorption of said medium in this second bandwidth depending on the intensity of said electromagnetic signal;
An optical probe comprising:
   means of sending an optical signal in said second bandwidth;
   opto-mechanical means arranged so that the optical signal passes through the absorbent medium;
   at least one photodetector arranged to receive the optical signal after having passed through the absorbent medium.

Advantageously, the active medium can comprise a solid or epitaxial semiconductor material on a substrate that is transparent to the optical signal, and the wavelength of the optical signal is then chosen to be greater than the absorption wavelength of this semiconductor material, the modification of the absorption being performed by Franz-Keldysh effect. The active medium can also be a symmetrical quantum well structure, the wavelength of the optical signal is then more or less adjacent to that of an inter-band or intra-band transition of said structure, the modification of the absorption being achieved by quantumly confined Stark effect. For example, the structure comprises a stack with several tens of flat layers, parallel to each other and a few tens of Angstroms thick, the constituent materials of the layers being alternately Ga_{0.53}In_{0.47}As and Al_{0.52}In_{0.48}As, the layers being epitaxial on an iron-doped semi-insulating InP substrate. The active medium can also be a dissymmetrical quantum well structure. In this case, the wavelength of the optical signal is equal to that of an inter-band or intra-band transition of said structure.

Advantageously, the active medium comprises a diffraction array adapted to operate in the bandwidth of the electromagnetic signal. If the medium has a quantum structure, the part of the electromagnetic signal diffracted by said array then has a direction more or less parallel to the mean plane of the layers of constituent materials of the quantum well structure.

Advantageously, the active medium comprises at least one antenna adapted to the first bandwidth of the signal to be detected, the optical signal being focused by the sending means in the vicinity of said antenna. In this case, the active medium can comprise a hemispherical lens centered on the antenna and produced in a material that is more or less transparent to the electromagnetic signal. It is also possible to use an active medium that has, in the area of the antenna, the form of a thin membrane, the thickness of said membrane being very much less than the mean wavelength of the electromagnetic signal.

Advantageously, the optical probe can operate by reflection, the sensor comprising optical means able to reflect the optical signal after it has passed through the absorbent medium. If the medium includes an antenna, the antenna can comprise at least one electrode used as mirror for the optical signal. It is also possible to improve the absorption of the optical signal by using a resonant optical cavity in which the active medium is located, the optical signal being focused by the sending means in the vicinity of said cavity. In this context, the opto-mechanical means comprise at least one separation optic placed so as to separate the sent optical signal before passing through the active medium from the optical signal reflected by the active medium. The separation of the sent and received beams can be obtained by using a polarized optical signal, the reflection and transmission coefficients of the separation optic then depending on the polarization of said signal.

Advantageously, the optical probe can also include a reference optical pathway comprising:
second opto-mechanical means arranged so that a part of the optical signal does not pass through the absorbent medium;
at least one second photodetector arranged to receive said part of the signal.

The optical signal is sent in the ultraviolet range or in the visible range or in the infrared range.

The invention also applies to a matrix or an array comprising a plurality of individual sensors, having the above characteristics, the individual photodetectors then being grouped together in a matrix of CCD (Charge-Coupled Device) type.

In this case, it is preferable for the active medium to be common to all the individual sensors of the matrix and for the sending means also to be common to all the individual sensors of the matrix, the single optical signal sent being separated into a plurality of individual signals dedicated to each individual sensor by means of a matrix of micro-optics.

### BRIEF DESCRIPTION OF THE DRAWINGS

The invention will be better understood, and other advantages will become apparent, on reading the description that follows, given by way of nonlimiting example, and with the help of the appended figures in which:

FIG. 1 represents the schematic diagram of operation of a sensor according to the invention;

FIGS. 2 and 3 represent the absorption variations as a function of time and the amplitude of the electrical field of the incident electromagnetic signal on the active medium of the sensor for two different absorption variations;

FIGS. 4a and 4b represent the absorption variations as a function of the wavelength of the optical signal in the presence or in the absence of electrical field from the electromagnetic signal, in the case where the active medium is of semiconductor type;

FIGS. 5a, 5b and 6a, 6b represent the absorption variations as a function of the wavelength of the optical signal in the presence or in the absence of electrical field of the electromagnetic signal, in the case where the active medium is of quantum well type;

FIG. 7 represents the schematic diagram of operation of a sensor according to the invention comprising an antenna;

FIG. 8 represents a possible form of the antenna;

FIGS. 9 and 10 represent a first and a second variant of the arrangement of FIG. 7;

FIG. 11 represents a sensor according to the invention, the active medium of which comprises a diffraction array;

FIG. 12 represents a first possible arrangement of a sensor comprising an optical probe operating by reflection;

FIG. 13 represents a second possible arrangement of a sensor comprising an optical probe operating by reflection;

FIG. 14 represents an example of processing of the signals from the optical probe;

FIG. 15 represents a sensor matrix according to the invention;

FIGS. 16 and 17 represent two possible applications of the device of FIG. 15.

### DETAILED DESCRIPTION OF THE DRAWINGS

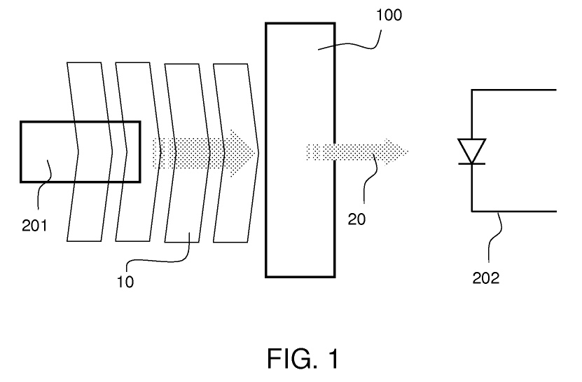

A sensor according to the invention is represented in FIG. 1. The electromagnetic signal 10 to be detected is sent in a first bandwidth. The sensor comprises:
An active medium 100 lit by said electromagnetic signal 10, absorbent in a second electromagnetic bandwidth, the absorption of said medium in this second bandwidth depending on the intensity of said electromagnetic signal;
An optical probe 200 comprising:
   means 201 of sending an optical signal 20 in said second bandwidth;
   opto-mechanical means arranged so that the optical signal 20 passes through the absorbent medium 100;
   at least one photodetector 202 arranged to receive the optical signal 20 after having passed through the absorbent medium 100.

To detect the continuous electromagnetic signal, the physical effect that modifies the absorption of the active medium in the presence of the electromagnetic signal should cause absorption fluctuations with non-zero mean.

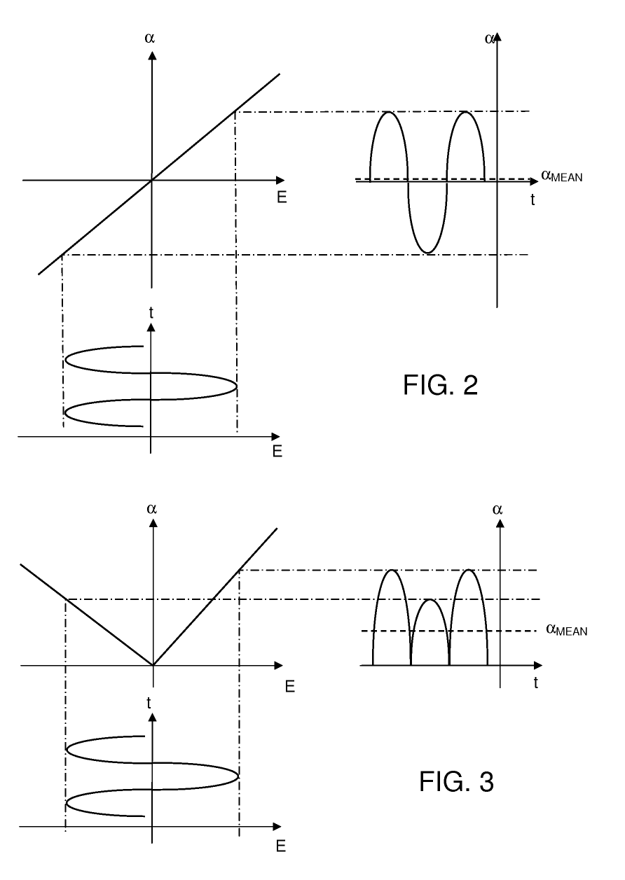

FIGS. 2 and 3 illustrate this principle. FIG. 2 represents a material of which the absorption α as a function of the electromagnetic field E of the electromagnetic signal is represented by a curve with odd symmetry centered on the zero electromagnetic field E. In this case, the absorption α follows the sinusoidal variations of the field E as a function of time and the mean variation α_{MEAN} is zero. This variation is represented by a broken line in FIG. 2. Such a material would not be appropriate for detection. However, as illustrated in FIG. 3, if the absorption α as a function of the electromagnetic field E of the electromagnetic signal is not a curve with odd symmetry, then the absorption α does not follow the sinusoidal variations of the field E as a function of time and the mean variation α_{MEAN} is no longer zero. In the case of FIG. 3, the absorption coefficient remains positive whatever the sign of the electromagnetic field E. In this latter case, the speed of the physical phenomenon inducing the absorption variation limits the electromagnetic bandwidth of the sensor.

The measurement of the mean absorption variation, by probing the active medium with an optical probe, will make it possible to quantify the power of the incident electromagnetic wave on the sensor. This measurement can be performed, for example, with a photodiode, the sensitivity of which is adapted to the wavelengths of the sent optical signal and the bandwidth of which is less than the frequency of the electromagnetic signal to be characterized.

There are various types of material presenting absorption coefficients α with non-zero mean variation.

A first type of active medium consists of a semiconductor which can be solid or epitaxial on a substrate that is transparent to the optical signal. More specifically, for the substrate to be transparent, it is sufficient for the wavelength of the optical signal to be greater than the absorption wavelength of the substrate. The modification of the absorption in the active medium is due to the Franz-Keldysh effect induced by the electrical field of the incident electromagnetic signal. This effect is independent of the sign of the electrical field. Consequently, the variation of the absorption of the active medium is non-zero on average. The Franz-Keldysh effect is a rapid effect, the absorption variation taking place in times less than 100 femtoseconds, enabling electromagnetic signals in the terahertz frequency domain to be detected.

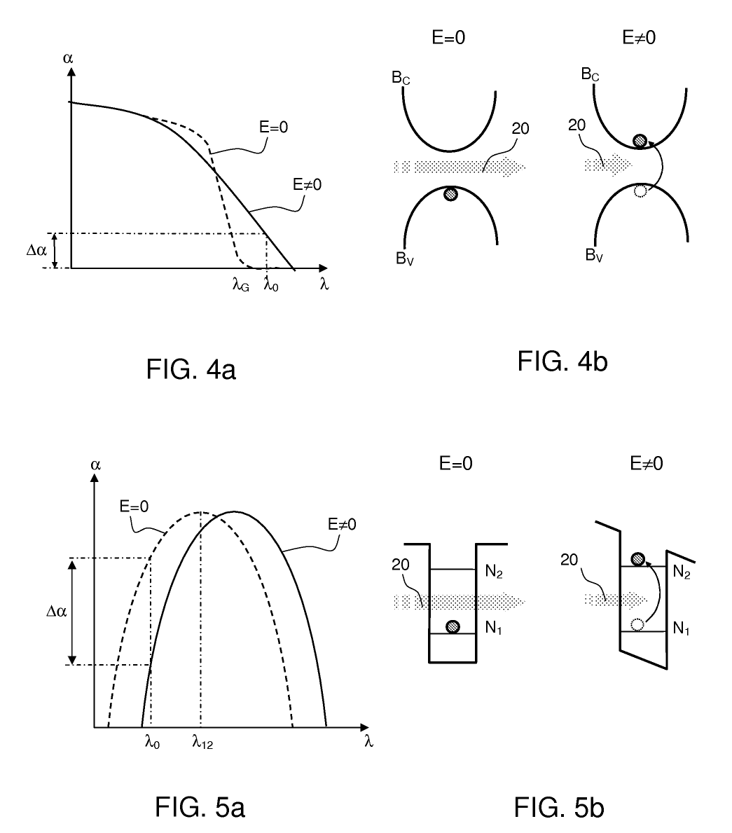

FIG. 4a represents the absorption as a function of the wavelength for a semiconductor material. The solid-line curve denoted E≠0 represents the absorption in the presence of the electromagnetic signal and the broken-line curve denoted E=0 represents the absorption in the absence of the electromagnetic signal. The variation of the absorption coefficient denoted Δα is maximum for wavelengths λ₀ very slightly greater than the absorption wavelength λ_{g} of the semiconductor material. Thus, as can be seen in FIG. 4b which conventionally represents the energy levels of the valency B_{V} and conduction B_{C} bands of the semiconductor material, if the electromagnetic field E is zero, an optical signal with the wavelength λ₀ is transmitted without absorption. If, on the other hand, the field E is no longer zero, the wavelength λ₀ is absorbed. In this case, an electronic transition takes place between the valency band and the conduction band, symbolized by the upward movement of an electron in FIG. 4b. The absorption contrast generated by the presence or absence of an electrical field is maximum.

In order to increase the sensitivity to the electrical field of the electromagnetic signal, the semiconductor active medium can be replaced by a stack of layers of material forming symmetrical quantum wells. As indicated in FIG. 5b, in the absence of applied field E, these wells present discrete energy levels N₁ and N₂. The application of an electrical field E perpendicular to the plane of the layers is reflected in a variation of the energy difference between the states of the wells; this effect is called quantumly confined Stark effect. This variation of the energy difference results in a modification of the optical absorption as a function of the wavelength as illustrated in FIG. 5a. The solid-line curve denoted E#0 represents the absorption of the quantum well structure in the presence of the field E and the broken-line curve denoted E=0 represents the absorption of the quantum well structure in the absence of field E. In this case, as can be seen in FIG. 5b, if the electromagnetic field E is zero, a wavelength λ₀ close to the wavelength λ₁₂ of an inter-band or intra-band transition of the quantum well structure is transmitted without absorption. If, however, the field E is no longer zero, the wavelength λ₀ is absorbed, provoking electronic transitions from the level N₁ to the level N₂. Thus, the absorption variation Δα induced by the inter-level energy variation is maximized.

For a symmetrical structure, this effect is independent of the sign of the applied electrical field, so enabling continuous electromagnetic signals to be detected.

Furthermore, this effect is rapid and makes it possible to detect electromagnetic fields up to the terahertz frequency domain. Finally, the quantum confinement is reflected in an increased sensitivity of the absorption to the electromagnetic field E.

As an example, a structure with multiple quantum wells forming the active medium consists of a stack comprising 50 flat layers, parallel to each other and 100 Angstroms thick, the stack having an overall thickness of 500 nanometers. The constituent materials of the layers are alternately Ga_{0.53}In_{0.47}As and Al_{0.52}In_{0.48}As. These layers are epitaxial on an iron-doped semi-insulating InP substrate. The wavelength corresponding to the inter-band transition in a quantum well is 1.55 microns.

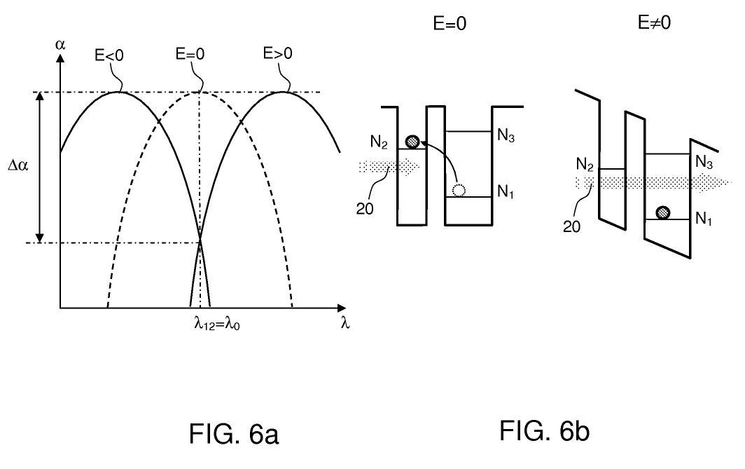

It is also possible to use a stack of dissymmetrical quantum wells by producing a structure in which the width of the lower-level well is different from that of the higher-level well as indicated in FIG. 6b. This dissymmetry makes it possible to increase the sensitivity to the electromagnetic field. As previously, the application of an electrical field perpendicular to the plane of the layers is reflected in a variation of the energy difference between the states of the quantum multi-well. This variation of the energy difference leads to a modification of the optical absorption as a function of the wavelength as illustrated in FIG. 6a. The solid-line curves denoted E<0 and E>0 represent the absorption of the quantum well structure in the presence of field E and the broken-line curve denoted E=0 represents the absorption of the quantum well structure in the absence of field E. The solid-line curves are symmetrical. The wavelength λ₀ of the optical signal is chosen according to the configuration of the wells, so as to optimize the detection. In this case, as can be seen in FIG. 6b, it is preferable for the wavelength λ₀ to be chosen to be equal to the wavelength λ₁₂ of the transition of the quantum well structure. Thus, if the electromagnetic field E is zero, the wavelength λ₀ is absorbed, provoking electronic transitions from the level N₁ to the level N₂. If, however, the field E is no longer zero, the wavelength λ₀ is transmitted. Thus, the absorption variation Δα induced by the inter-level energy variation is identical irrespective of the sign of E, inducing an absorption variation that is non-zero on average.

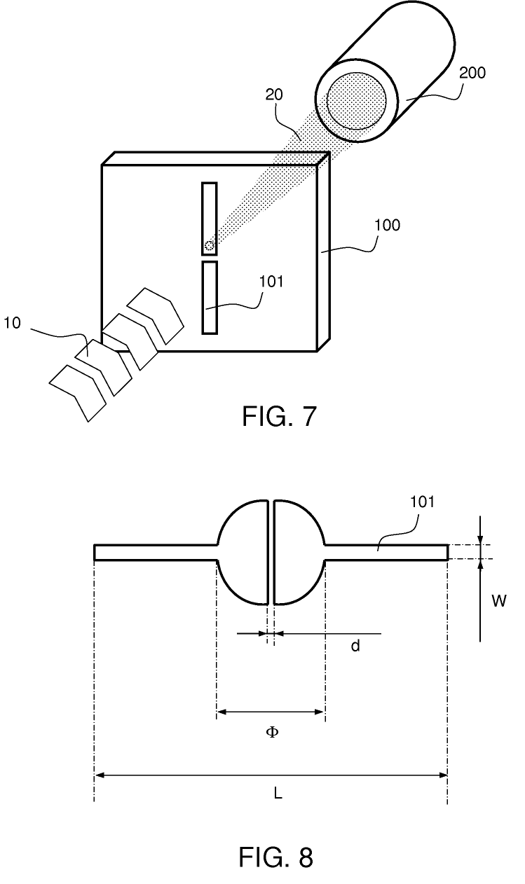

To improve the sensitivity of the sensor and/or to change the direction of the field of the electromagnetic signal so as to improve the sensitivity of the active medium, it is interesting to have on the active medium means of concentrating the electromagnetic signal to be detected. The simplest way to proceed is to deposit on the surface of the semiconductor an antenna 101 adapted to the frequency of the wave to be detected as indicated in FIG. 7. This makes it possible to concentrate the electrical field to be detected in proportion to the quality figure of the antenna at the level of the inter-electrode space of the antenna. The layout of the inter-electrode space helps to locally increase the electrical field. This inter-electrode space should present a capacitance C that is low enough for the characteristic time τ corresponding to its charge or more generally to its change of state to be less than the period of the electromagnetic signal to be detected.

with τ=RC, R being the radiation resistance of the antenna.

The characteristics and the form of the antenna are adapted according to the frequency and bandwidth characteristics of the electromagnetic signal. In FIG. 7, the antenna has the simple form of a dipole. In this case, if the electromagnetic signal has an effective mean wavelength Λ, the length of the antenna should be more or less Λ/2. Other forms are also possible, such as the so-called butterfly antennas and the so-called spiral antennas which present the advantage of a very wide bandwidth.

The material of the antenna can be gold.

Of course, the optical signal must be focused in the vicinity of said antenna, at the point where the concentration of the electromagnetic signal and the absorption variation that it induces are greatest.

As an example, FIG. 8 represents an antenna 101 appropriate for detecting waves having frequencies in the terahertz vicinity. This dipole-type antenna consists of two symmetrical and identical parts. Its overall wavelength L is 40 microns. Each part comprises a strand, the width W of which is 800 nanometers. Each strand is terminated by a semicircle, the diameter of which is 4 microns. The slot separating the two semicircles has a width d of 200 nanometers. This slot constitutes the inter-electrode space of the antenna. The optical signal from the probe is reflected on the two semi-circles. Since the width of the slot is very much less than the optical wavelength, all the surface formed by the two semicircles is reflecting. This antenna presents a resonance about 1 terahertz. It thus fixes the detection band at a few percent.

In this case, the optical signal from the probe is focused in the center of the two semicircles.

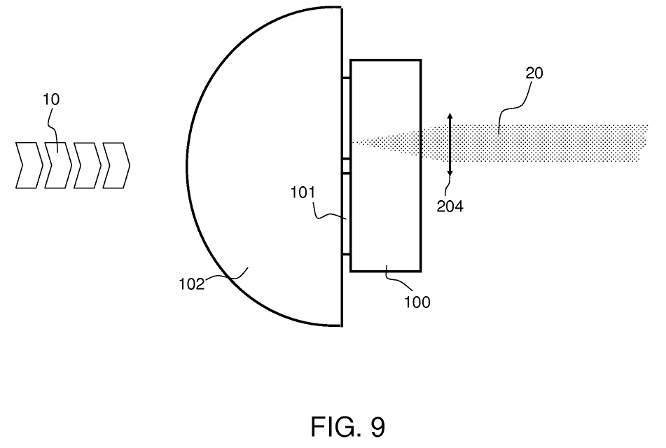

To improve the detection sensitivity, the gain of the antenna can be increased thanks to a hemispherical lens 102 centered on the antenna as indicated in FIG. 9. The material used for this lens must be transparent to the electromagnetic signal to be characterized. Thus, such a lens can be produced using sapphire, quartz, PTFE, polyethylene or a semiconductor material with low concentration of free carriers such as ultra-resistive silicon or semi-insulating gallium arsenide.

As an example, a hemispherical lens with a diameter of 5 millimeters can be centered and glued on the antenna of FIG. 8.

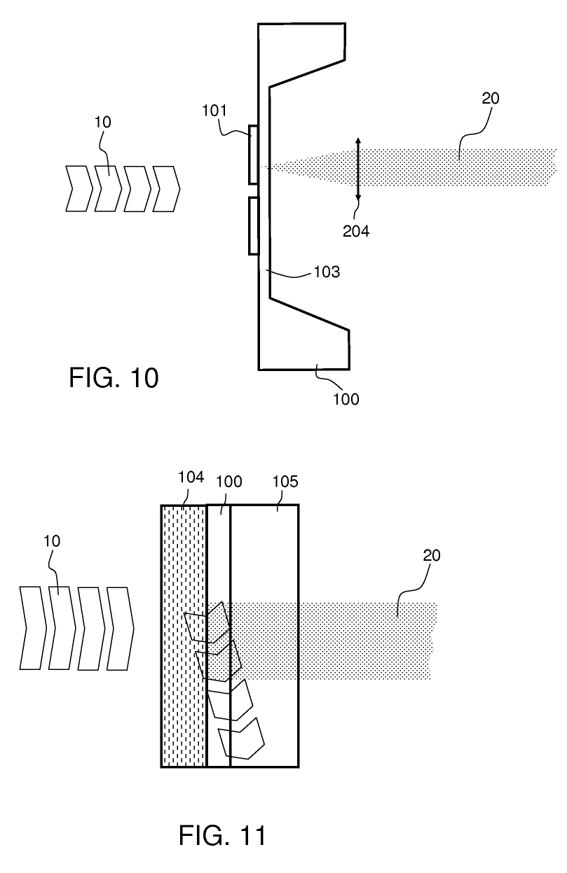

A second embodiment to increase the gain of the antenna is indicated in FIG. 10. The antenna is produced on a membrane 103, the effective thickness of which is very much less than the wavelength of the electromagnetic wave to be characterized. Thus, the active medium remains transparent to the electromagnetic signal.

It is known that the quantum well structures are sensitive only to electrical fields perpendicular to the mean plane of the layers. As has been seen, it is possible to rectify the field of the electromagnetic signal by means of an antenna. It is also possible to obtain this effect by means of a diffraction array 104 arranged on the active medium and adapted to operate in the bandwidth of the electromagnetic signal as indicated in FIG. 11. The array is then arranged so that the part of the electromagnetic signal diffracted by said array has a direction more or less parallel to the mean plane of the layers of material forming the quantum well structure. Thus, the polarization of the electromagnetic signal which is perpendicular to the direction of propagation is more or less perpendicular to the plane of the layers of the active medium.

It has been seen that the choice of the wavelength of the optical signal conditions the performance of the system. It is advantageous to choose sources emitting over a narrow and stable spectral band. Lasers are particularly well suited to this type of device. The optical signal sending means are, for example, lasers of DFB (Distributed FeedBack) type. These lasers generally emit in the near infrared. They can be fiber drawn, the emission from the laser being transmitted in a single-mode optical fiber. Their output power can easily be modulated.

The optical probe can operate either by transmission or by reflection. The second mode of operation presents the advantage of dissociating the electromagnetic signal and the optical signal which can be positioned either side of the active medium. In this case, if the medium comprises an antenna, one of the electrodes of this antenna can be used as mirror for the optical signal.

To improve the detection sensitivity, the effective interaction length of the probe with the active medium can be increased. To do this, the active medium is placed in a resonant optical cavity. This can be formed:
on a first side of the active medium, by the metal electrode of the antenna which can have a reflection coefficient close to 100%, and
on the opposite side of the active medium, by a mirror which can be a metal, dielectric or Bragg mirror based on dielectric or semiconductor materials. The reflectivity of this second mirror is optimized to maximize the variation of the back-transmitted optical power for each cavity as a function of the absorption variation in the active medium.

The optical thickness of the resonant optical cavity should be chosen so that the go and return journeys of the optical signal interfere positively.

In the case of reflection-mode operation, it is necessary for the probe to include opto-mechanical means arranged so as to separate the optical signal sent before passing through the active medium from the optical signal reflected by the active medium.

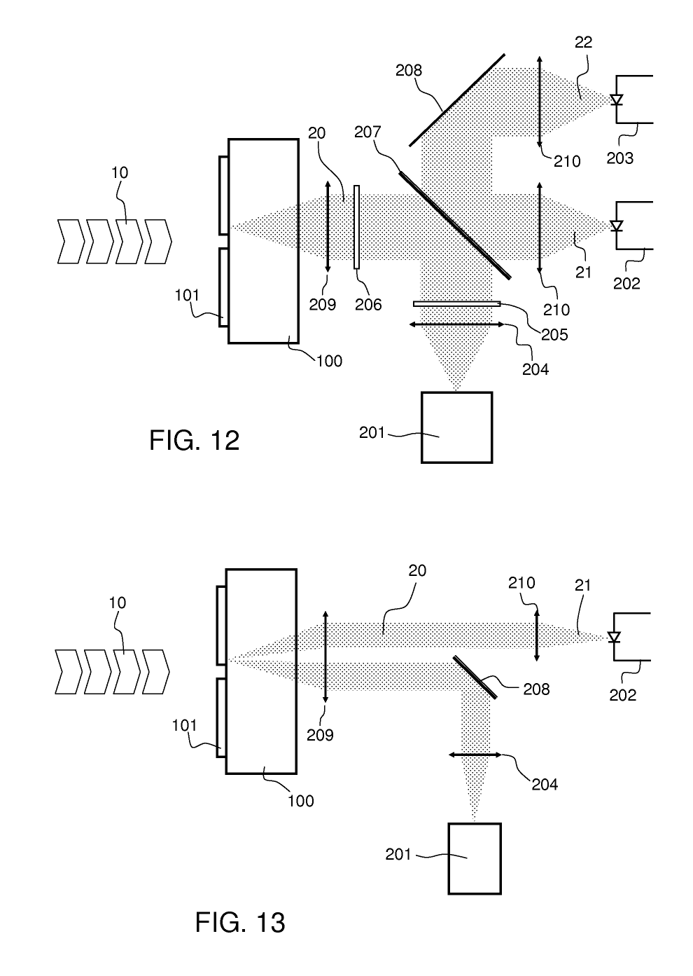

FIG. 12 shows a first exemplary embodiment of an optical probe operating by reflection and including such means. More specifically, the probe comprises:
means 201 of sending the optical signal. These sending means are, for example, a laser diode emitting in the visible or infrared radiation range;
opto-mechanical means arranged so that the optical signal passes through the absorbent medium. These means comprise:
   collimation and focusing lenses 204, 209 and 210;
   a separating plate 207. If the sending source sends a linearly polarized light, this plate can be a polarization separating plate. In this case, the reflection and transmission coefficients of this plate depend on the polarization of the signal and are optimized so as to reflect and transmit the optical signal with balanced efficiencies. To change the polarization of the incident optical signal it is possible, for example, to place a quarter-wave plate 206 between the separating plate 207 and the active medium 100. In this case, if the plate is appropriately oriented, the polarization of the optical signal reflected by the active medium and having passed twice through the quarter-wave plate has rotated 90 degrees relative to the initial polarization of the signal. This device can be complemented by means of a half-wave adjusting plate 205 or by means of mechanical adjustments making it possible, for example, to orient the sending source;
at least one photodetector 202 arranged to receive the optical signal 21 after having passed through the absorbent medium.

FIG. 13 shows a second exemplary embodiment of an optical probe operating by reflection. More specifically, the probe comprises:
means 201 of sending the optical signal 20;
first opto-mechanical means arranged so that the optical signal passes through the absorbent medium. These means comprise:
   a collimation lens 204, a return mirror 208 and a focusing lens 209 arranged at the output of the sending means 201 and which make it possible to focus the optical signal on the absorbent medium;
   a focusing lens 210;
   at least one photodetector 202 arranged to receive the optical signal 21 after having passed through the absorbent medium and the lenses 209 and 210.

The optical probe can also comprise a reference optical pathway as indicated in FIG. 12, comprising:
second opto-mechanical means 208 arranged so that a part of the optical signal 22 does not pass through the absorbent medium;
at least one second photodetector 203 arranged so as to receive said part of the signal called reference signal.

This arrangement makes it possible to obtain a detection independent of the intensity variations of the optical signal sent.

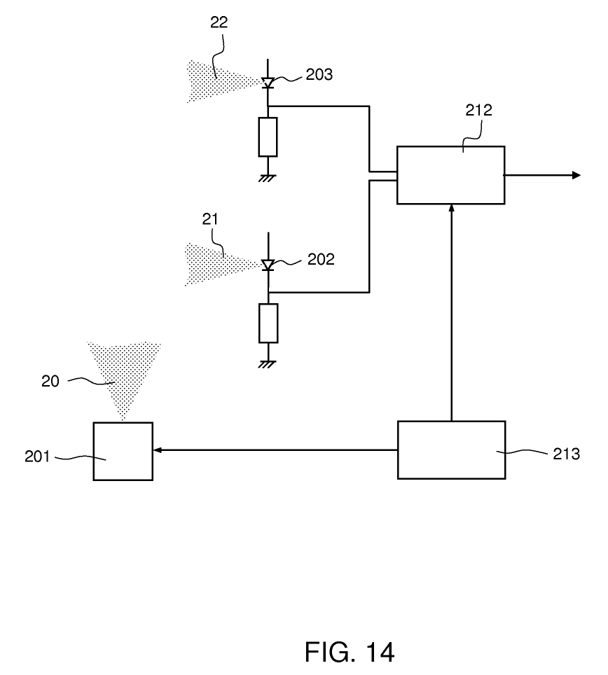

FIG. 14 illustrates a detection device of this type. The photodetectors 202 and 203 are photodiodes comprising a load resistor 211. The output of these photodiodes is connected to the inputs of a synchronous detection function 212. A modulator 213 sends a modulated signal which controls the modulation of the optical signal 20 sent by the sending means. This modulated signal is also supplied to the synchronous detection function. At the output of the synchronous detection function, a voltage is obtained that is proportional to the difference in intensity of the measurement signal 21 and the reference signal 22. In this case, it is interesting that, in the absence of an electromagnetic signal, the measurement and reference signals are equal. Thus, the absence of the signal gives a zero voltage at the synchronous detection output. It is easy to obtain this signal equality by adjusting the various optical parameters of the optical probe.

It is, of course, possible to combine a plurality of individual sensors to form a matrix or an array of sensors. In this case, the individual photodetectors are then grouped together in a matrix of CCD (Charge-Coupled Device) type.

It is also preferable, in this case, for the active medium to be common to all the individual sensors of the matrix and for the sending means also to be common to all the sensors of the matrix, the single signal that is sent being separated into a plurality of individual signals dedicated to each individual sensor by means of a matrix of micro-optics.

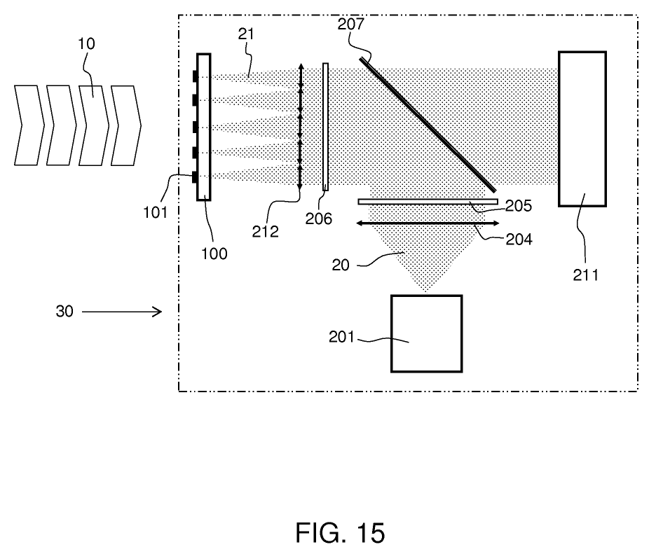

FIG. 15 represents a detection device 30 comprising such a matrix. It comprises:
an active medium 100 comprising a plurality of detection areas. Each area can include an antenna 101. In this case, the separation between the various antennas gives the spatial resolution of the device, bearing in mind that it is essential to avoid too great an overlap of the antenna reception lobes;
means 201 of sending the optical signal. These sending means are, for example, a laser diode emitting in the visible or infrared radiation range;
opto-mechanical means arranged so that the optical signal passes through the absorbent medium 100 and is focused in the detection areas. These means comprise:
   a collimation lens 204 and an array of micro-lenses 212 handling the focusing of the optical signal on the detection areas;
   a separating plate 207 operating by polarization. This plate is placed between a half-wave plate 205 and a quarter-wave plate 206;
a CCD array or matrix 211 receiving the optical signals reflected by the various detection areas.

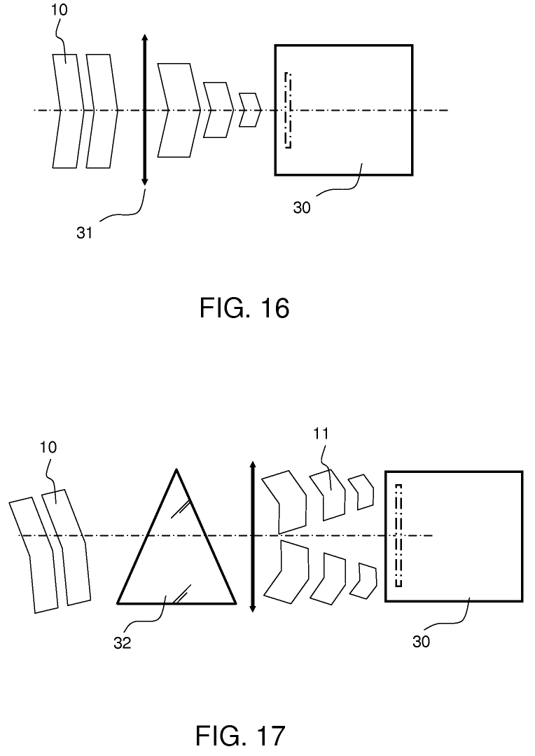

Such devices can be used to carry out terahertz imaging. In this case, as indicated in FIG. 16, a focusing optic 31 that is transparent to the terahertz waves is positioned in front of the detection device 30.

It can also be used to carry out terahertz spectroscopy. In this case, as indicated in FIG. 17, a dispersion prism or a diffraction array 32 and a focusing lens 33 are positioned in front of the detection device 30. An electromagnetic signal which has the form of a flat wave is thus broken down by the latter device into monochromatic signals focused on the array or matrix of sensors.

1. A sensor of an electromagnetic signal sent in a first bandwidth, comprising:
An active medium lit by said electromagnetic signal, absorbent in a second electromagnetic bandwidth, the absorption of said medium in this second bandwidth depending on the intensity of said electromagnetic signal;
An optical probe comprising:
means of sending an optical signal (20) in said second bandwidth;
opto-mechanical means arranged so that the optical signal passes through the absorbent active medium;
at least one photodetector arranged to receive the optical signal after having passed through the absorbent medium.

2. The sensor as claimed in claim 1, wherein, on the one hand, the active medium consists of a solid or epitaxial semiconductor material and on the other hand the wavelength of the optical signal is greater than the absorption wavelength of the semiconductor material, the absorption being performed by Franz-Keldysh effect.

3. The sensor as claimed in claim 1, wherein, on the one hand, the active medium is a symmetrical quantum well structure and, on the other hand, the wavelength of the optical signal is more or less adjacent to that of an inter-band or intra-band transition of said structure.

4. The sensor as claimed in claim 3, wherein the structure comprises a stack with several tens of flat layers, parallel to each other and a few tens of Angstroms thick, the constituent materials of the layers being alternately Ga_{0.53}In_{0.47}As and Al_{0.52}In_{0.48}As, the layers being epitaxial on an iron-doped semi-insulating InP substrate.

5. The sensor as claimed in claim 1, characterized wherein, on the one hand, the active medium is a dissymmetrical quantum well structure and, on the other hand, the wavelength of the optical signal is more or less equal to that of an inter-band or intra-band transition of said structure.

6. The sensor as claimed in claim 1, wherein the active medium comprises a diffraction array adapted to operate in the bandwidth of the electromagnetic signal.

7. The sensor as claimed in claim 3, wherein the array is configured so that the part of the electromagnetic signal diffracted by said array has a direction more or less parallel to the mean plane of the layers of constituent materials of the quantum well structure.

8. The sensor as claimed in claim 1, wherein the active medium comprises at least one antenna adapted to the first bandwidth of the signal to be detected, the optical signal being focused by the sending means in the vicinity of said antenna.

9. The sensor as claimed in claim 8, wherein the antenna is of dipole type and consists of two symmetrical and identical parts, each part comprising a strand terminated by a semicircle, the slot separating the two parts having a width very much less than the wavelength of the optical signal.

10. The sensor as claimed in claim 8, wherein the active medium comprises a hemispherical lens centered on the antenna and produced in a material that is more or less transparent to the electromagnetic signal.

11. The sensor as claimed in claim 8, wherein the active medium has, in the area of the antenna, the form of a thin membrane, the thickness of said membrane being less than the mean wavelength of the electromagnetic signal.

12. The sensor as claimed in claim 1, wherein the optical probe operates by reflection, the sensor comprising optical means able to reflect the optical signal after it has passed through the absorbent medium.

13. The sensor as claimed in claim 8, wherein the antenna comprises at least one electrode used as a mirror for the optical signal.

14. The sensor as claimed in claim 13, comprising a resonant optical cavity in which the active medium is located, the optical signal being focused by the sending means in the vicinity of said cavity.

15. The sensor as claimed in claim 12, wherein the opto-mechanical means comprise at least one separation optic placed so as to separate the sent optical signal before passing through the active medium from the optical signal reflected by the active medium.

16. The sensor as claimed in claim 15, wherein the optical signal is polarized and the reflection and transmission coefficients of the separation optic depend on the polarization of said signal.

17. The sensor as claimed in claim 1, wherein the optical probe also includes a reference optical pathway comprising:
second opto-mechanical means arranged so that a part of the optical signal does not pass through the absorbent medium;
at least one second photodetector arranged to receive said part of the signal.

18. The sensor as claimed in claim 1, wherein the optical signal is sent in the ultraviolet range or in the visible range or in the infrared range.

19. A matrix or array of sensors comprising a plurality of individual sensors, wherein said sensors are in accordance with claim 1 and the individual photodetectors are grouped together in a matrix of CCD type.

20. The matrix or array of sensors as claimed in claim 19, wherein the active medium is common to all the individual sensors of the matrix.

21. The matrix or array of sensors as claimed in claim 19, wherein the sending means are common to all the sensors of the matrix, the single signal sent being separated into a plurality of individual signals dedicated to each individual sensor by means of a matrix of micro-optics.
